(19) United States
(12) Patent Application Publication
(10) Pub. No.: US 2023/0345839 A1
(43) Pub. Date: Oct. 26, 2023

(54) PIEZOELECTRIC FILM WITH CARBON NANOTUBE-BASED ELECTRODES

(71) Applicant: Kureha America, Inc., Houston, TX (US)

(72) Inventors: Tatsuya Yaguchi, Houston, TX (US); Mayu Komatsu, Houston, TX (US)

(73) Assignee: Kureha America, Inc., Houston, TX (US)

(21) Appl. No.: 18/137,649

(22) Filed: Apr. 21, 2023

Related U.S. Application Data
(60) Provisional application No. 63/333,323, filed on Apr. 21, 2022.

(51) Int. Cl. H10N 30/87; H10N 30/20; H10N 30/00; H10N 30/857; B82Y 15/00

(52) U.S. Cl. CPC H10N 30/878; H10N 30/206; H10N 30/1051; H10N 30/857; B82Y 15/00; G06F 3/04144

(57) ABSTRACT

A piezoelectric device includes a piezoelectric film and a carbon-nanotube (CNT)-based electrode layer directly disposed on at least one side of the piezoelectric film. The CNT-based first electrode layer has a sheet resistance of less than 300 ohm/sq.

### CROSS-REFERENCE TO RELATED APPLICATIONS

This application claims the benefit of priority under 35 U.S.C. § 119(e) to U.S. Provisional Patent Application Ser. No. 63/333,323, filed on Apr. 21, 2022, which is hereby incorporated by reference herein in its entirety.

### BACKGROUND

Piezoelectric devices may be used for applications in many areas including, but not limited to, biomedicine, defense technology, nano-devices, micro electromechanical systems (MEMS) and mechanical energy harvesters (MEHs). Broadly speaking, piezoelectric devices may be useful for any application involving a conversion between mechanical energy and electrical energy. Examples include input devices such as touch sensor devices (e.g., touchpads or touch sensor devices) that are widely used in a variety of electronic systems. A touch sensor device typically includes a sensing region, often demarked by a surface, in which the touch sensor device determines the presence, location and/or motion of one or more input objects. Touch sensor devices may be used to provide interfaces for the electronic system. For example, touch sensor devices are often used as input devices for larger computing systems (such as opaque touchpads integrated in, or peripheral to, notebook or desktop computers or transparent touchpads integrated in touch displays).

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a piezoelectric device comprising: a piezoelectric film; and a first carbon-nanotube (CNT)-based electrode layer directly disposed on at least one side of the piezoelectric film, wherein the CNT-based first electrode layer has a sheet resistance of less than 300 ohm/sq.

In general, in one aspect, embodiments relate to a method of manufacturing a piezoelectric device, the method comprising: obtaining a carbon nanotube (CNT) dispersion; coating a piezoelectric film with the CNT dispersion to obtain a CNT-based electrode layer directly disposed on the piezoelectric film; and curing the CNT-based electrode layer, wherein the CNT-based electrode layer has a sheet resistance of less than 300 ohm/sq.

In general, in one aspect, embodiments relate to a piezoelectric input device comprising: a piezoelectric device, comprising: a piezoelectric film; and a first carbon-nanotube(CNT)-based electrode layer directly disposed on at least one side of the piezoelectric film, wherein the CNT-based first electrode layer has a sheet resistance of less than 300 ohm/sq and forms a plurality of receiver electrodes; and a processing system for determining the position of the input object based on resulting signals obtained from the plurality of receiver electrodes.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows an input device in accordance with one or more embodiments.

FIG. 2 shows a touch sensing system in accordance with one or more embodiments.

FIG. 3 shows an energy harvesting system in accordance with one or more embodiments.

FIG. 4 shows an actuator in accordance with one or more embodiments.

FIGS. 5A, 5B, and 5C show example piezoelectric devices in accordance with one or more embodiments.

FIGS. 6A and 6B show electrode patterns in accordance with one or more embodiments.

FIG. 7 illustrates a method of manufacturing a piezoelectric device in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.)

may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include piezoelectric devices based on piezoelectric films with carbon nanotube (CNT)-based electrodes and a method of manufacturing piezoelectric devices based on PVDF piezoelectric films with CNT-based electrodes. The piezoelectric devices may be used in any application involving a conversion between mechanical energy and electrical energy. Embodiments of the disclosure as subsequently described have various advantages. For example, as discussed in detail below, a piezoelectric device in accordance with one or more embodiments is easy to manufacture, requires relatively few components, and provides good optical transparency. The optical transparency may make the piezoelectric device suitable for use in conjunction with displays. Further, a piezoelectric device in accordance with embodiments of the disclosure may be relatively flexible or bendable, thus making it suitable for non-rigid applications. Input devices (e.g., touch or force sensing input devices) based on the piezoelectric devices may have advantages over other touch sensing technologies. For example, in comparison to capacitive touch sensing, piezoelectric touch sensing in accordance with one or more embodiments is more robust to environmental influences such as moisture. Thus, piezoelectric devices in accordance with embodiments of the disclosure are particularly suitable for a wide range of applications and operating environments, including wet or even underwater environments, applications in which mechanical flexibility is required or desired, applications in which optical transparency is required or desired, etc. A detailed description is subsequently provided.

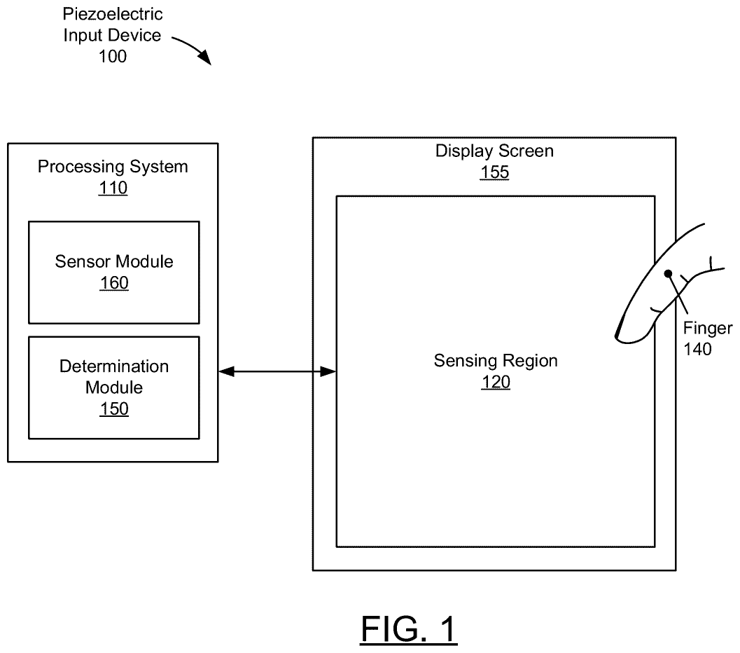

FIG. 1 is a block diagram of an example piezoelectric input device (100), in accordance with one or more embodiments. The piezoelectric input device (100) may be configured to perform a touch and/or force sensing to provide input to an electronic system (not shown). As used in this document, the term “electronic system” (or “electronic device”) broadly refers to any system capable of electronically processing information. Some non-limiting examples of electronic systems include personal computers, such as desktop computers, laptop computers, tablets, machinery and medical devices with at least some degree of computing capability, etc. Further example electronic systems include peripherals, such as data input devices (including remote controls, mice, haptic input devices or sensing devices including robotic probes, hands, pressure measurement devices, etc.), and data output devices (including display screens and printers). Other examples include remote terminals, kiosks, and video game machines (e.g., video game consoles, portable gaming devices, and the like). Other examples include communication devices (including cellular phones, such as smart phones), and media devices (including recorders, editors, and players such as televisions, set-top boxes, music players, digital photo frames, and digital cameras). Additionally, the electronic system could be a host or a slave to the input device.

In FIG. 1, the piezoelectric input device (100) is shown as a touch sensor device (e.g., “touchpad” or a “touch sensor device”) configured to sense input provided by one or more input objects in a sensing region (120). Example input objects include styli, fingers (140), etc.

The sensing region (120) encompasses any space above, around, in and/or near the input device (100) in which the input device (100) is able to detect user input (e.g., user input provided by one or more input objects). The sizes, shapes, and locations of particular sensing regions may vary widely from embodiment to embodiment.

The input device (100) may use any combination of sensor components and technologies to detect user input in the sensing region (120). The input device (100) includes one or more sensing elements for detecting user input. The sensing elements may be piezoelectric. When a force load is applied to a piezoelectric material (e.g., a non-centrosymmetric material whose polarization moves to positive or negative direction according to the direction of the applied force), the charge balance in the piezoelectric material changes. By measuring the induced voltage, the touch event associated with the force load may be determined, and the applied force may be calculated.

Some piezoelectric implementations utilize arrays or other regular or irregular patterns of receiver electrodes to pick up the induced voltages at different locations across the piezoelectric material associated with the sensing region (120). Accordingly, a location of the touch event in the input region (120) may be determined.

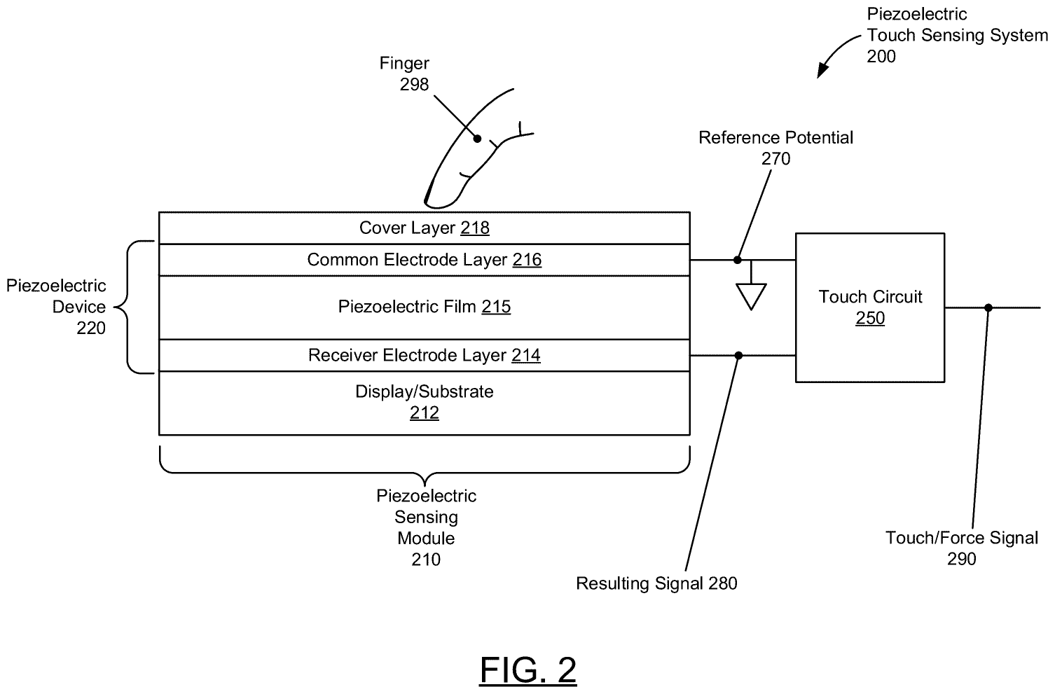

In FIG. 1, a processing system (110) is shown as part of the input device (100). The processing system (110) is configured to operate the hardware of the input device (100) to detect input in the sensing region (120). The processing system (110) includes parts of or all of one or more integrated circuits (ICs) and/or other circuitry components. For example, the processing system (110) may include the circuit components discussed below in reference to FIG. 2.

In some embodiments, the processing system (110) also includes electronically-readable instructions, such as firmware code, software code, and/or the like. In some embodiments, components composing the processing system (110) are located together, such as near sensing element(s) of the input device (100). In other embodiments, components of processing system (110) are physically separate with one or more components close to the sensing element(s) of the input device (100), and one or more components elsewhere. For example, the input device (100) may be a peripheral coupled to a computing device, and the processing system (110) may include software configured to run on a central processing unit of the computing device and one or more ICs (perhaps with associated firmware) separate from the central processing unit. As another example, the input device (100) may be physically integrated in a mobile device, and the processing system (110) may include circuits and firmware that are part of a main processor of the mobile device. In some embodiments, the processing system (110) is dedicated to implementing the input device (100). In other embodiments, the processing system (110) also performs other functions, such as operating display screens (155), driving haptic actuators, etc.

The processing system (110) may be implemented as a set of modules that handle different functions of the processing system (110). Each module may include circuitry that is a part of the processing system (110), firmware, software, or a combination thereof. In various embodiments, different combinations of modules may be used. For example, as shown in FIG. 1, the processing system (110) may include a determination module (150) and a sensor module (160). The determination module (150) may include functionality to determine when at least one input object is in a sensing region, signal to noise ratio, positional and/or force information of an input object, a gesture, an action to perform based on the gesture, a combination of gestures or other information, and/or other operations.

The sensor module (160) may include functionality to determine touch events. For example, the sensor module (160) may include sensory circuitry that is coupled to receiver electrodes, as further described below. The sensor module (160) may receive one or more resulting signals from the receiver electrodes disposed on a layer of piezoelectric material. The resulting signal may include desired signals, such as components caused by an input object exerting a force in the sensing region (120), and/or undesired signals, such as noise or interference.

Although FIG. 1 shows a determination module (150) and a sensor module (160), alternative or additional modules may exist in accordance with one or more embodiments. Example alternative or additional modules include hardware operation modules for operating hardware such as sensor electrodes and display screens (155), data processing modules for processing data such as sensor signals and positional and/or force information, reporting modules for reporting information, and identification modules configured to identify gestures, such as mode changing gestures, and mode changing modules for changing operation modes. Further, the various modules may be combined in separate integrated circuits. For example, a first module may be included at least partially within a first integrated circuit and a separate module may be included at least partially within a second integrated circuit. Further, portions of a single module may span multiple integrated circuits. In some embodiments, the processing system as a whole may perform the operations of the various modules.

In some embodiments, the processing system (110) responds to user input (or lack of user input) in the sensing region (120) directly by causing one or more actions. Example actions include changing operation modes, as well as graphical user interface (GUI) actions such as cursor movement, selection, menu navigation, and other functions. In some embodiments, the processing system (110) provides information about the input (or lack of input) to some part of the electronic system (e.g., to a central processing system of the electronic system that is separate from the processing system (110), if such a separate central processing system exists). In some embodiments, some part of the electronic system processes information received from the processing system (110) to act on user input, such as to facilitate a full range of actions, including mode changing actions and GUI actions.

In some embodiments, the input device (100) includes a touch screen interface, and the sensing region (120) overlaps at least part of an active area of a display screen (155). For example, the input device (100) may include substantially transparent sensor electrodes overlaying the display screen and provide a touch screen interface for the associated electronic system. The display screen may be any type of dynamic display capable of displaying a visual interface to a user and may include any type of light emitting diode (LED), organic LED (OLED), cathode ray tube (CRT), liquid crystal display (LCD), plasma, electroluminescence (EL), or other display technology. The input device (100) and the display screen (155) may share physical elements. For example, some embodiments may utilize some of the same electrical components for displaying and sensing. In various embodiments, one or more display electrodes of a display device may be configured for both display updating and input sensing. As another example, the display screen (155) may be operated in part or in total by the processing system (110).

Turning to FIG. 2, a piezoelectric touch sensing system (200), in accordance with one or more embodiments, is shown. The piezoelectric touch sensing system (200) includes a piezoelectric sensing module (210). The piezoelectric sensing module (210) may output one or more resulting signals (280), in response to the presence or absence of touch, e.g., by a finger (298) or any other input object. The resulting signal(s) (280) may be processed by a touch circuit (250) as discussed below.

The piezoelectric sensing module (210) may be used to provide touch sensing for all or part of the sensing region (120) shown in FIG. 1. The piezoelectric sensing module (210) may also provide a display for all or part of the display screen (155). The touch circuit (250) may be a component of the processing system (110).

In one or more embodiments, the piezoelectric sensing module (210) has multiple layers including a display (212) or a substrate (if no display is present), various layers for piezoelectric touch sensing (214, 215, 216) and a cover layer (218). In one embodiment, the display (212) is an OLED display. Multiple display layers may form the display (212). For example, an OLED display may include an organic emissive layer, an anode layer, a cathode layer, one or more conductive layers which may include a thin-film transistor (TFT) layer, etc. The stack of display layers may also include a display substrate. The display substrate may be a rigid or flexible glass or plastic substrate. The display (212) may alternatively be a microLED display a TFT display or any other type of display including the corresponding layers.

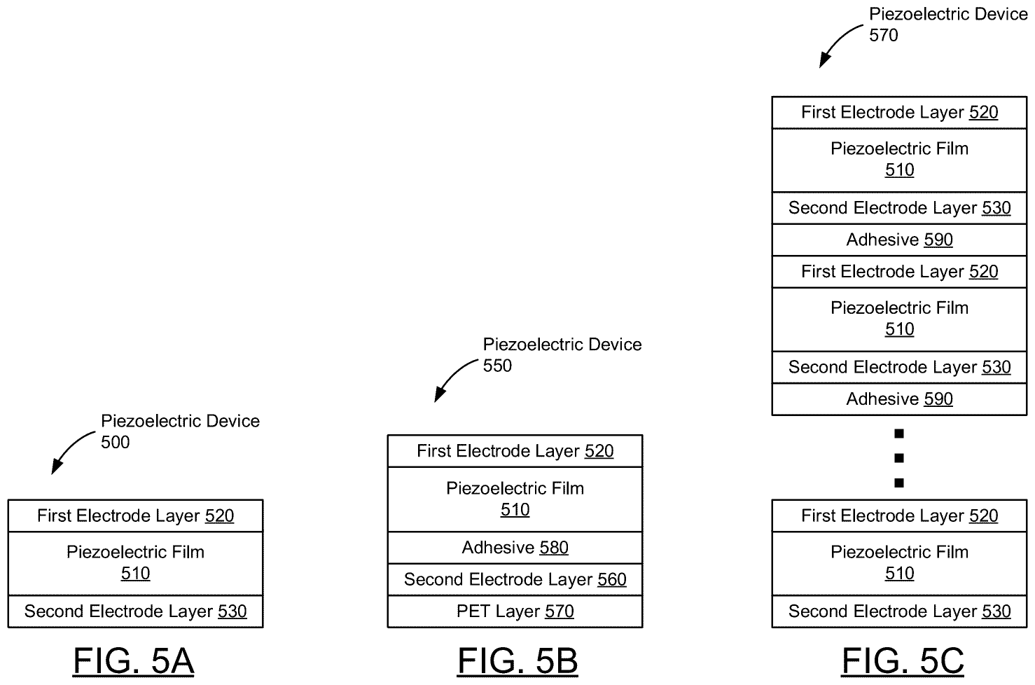

In one or more embodiments, the layers for piezoelectric touch sensing (214, 215, 216) form a piezoelectric device (220) and include a receiver electrode layer (214), a piezoelectric film (215), and a common electrode layer (216). The cover layer (218) may provide a touchable surface. The function of these layers is subsequently described. Further, a more detailed description of the piezoelectric device (220) is provided below in reference to FIGS. 5A and 5B.

In one or more embodiments, the receiver electrode layer (214), the piezoelectric film (215) and the common electrode layer (216) of the piezoelectric device (220) are arranged in a sandwich architecture where the piezoelectric material is in-between two layers of electrodes. Due to the piezoelectric effect associated with the piezoelectric material, when a force load is applied to the piezoelectric film (215), the charge balance across the piezoelectric film (215) changes. The change in charge balance may be registered as a voltage between a receiver electrode in the receiver electrode layer (214) and a common electrode in the common electrode layer (216). In one embodiment, the piezoelectric film is a polyvinylidene fluoride (PVDF) piezoelectric film. Other piezoelectric materials such as copolymers of PVDF, polylactic acid piezo-biopolymers, polyureas, polyurethanes, polyamides, polyacrylonitriles, a polyimides, polypropylenes, etc., may be used, without departing from the disclosure. Additional layers may be added to the piezoelectric film. The additional layers may include one or more of, for example, a hard coat layer, an index matching layer, an antistatic layer, etc. A description of a piezoelectric film is provided in PCT Patent Application No. PCT/JP2021/013199. PCT/JP2021/013199 is hereby incorporated by reference in its entirety.

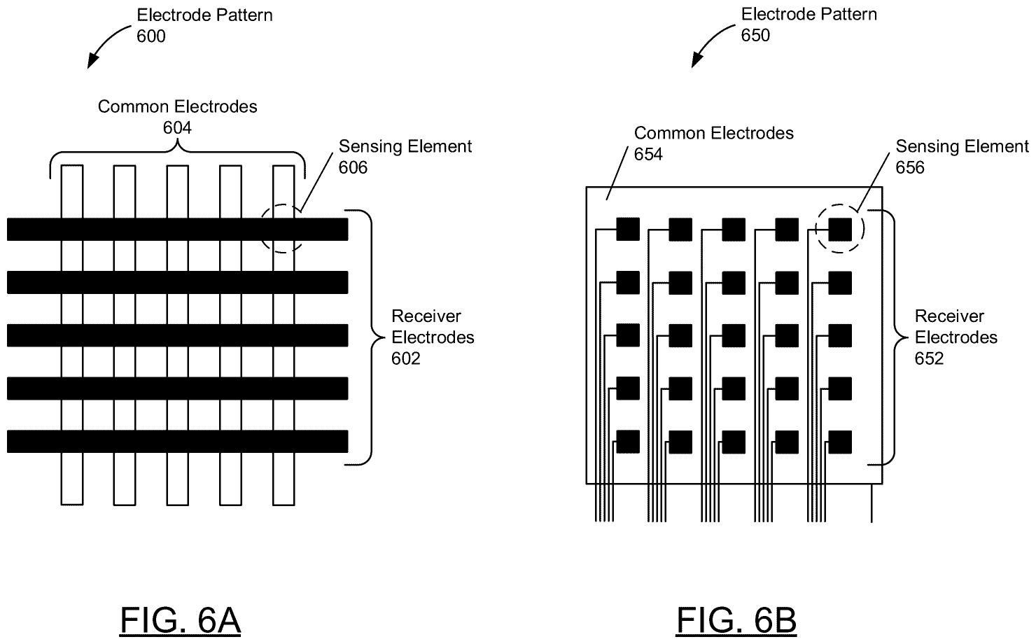

In one or more embodiments, the receiver electrode layer (214) and the common electrode layer (216) both include one or more electrodes configured to detect the change in the charge balance across the piezoelectric film (215). The electrodes may consist of a transparent conductive coating such as, carbon nanotubes (CNTs), doped CNTs, a mixture of CNTs with metal nanowires (e.g., silver nanowires), conductive polymers (e.g., PEDOT:PSS), graphene, metal mesh, etc. The common electrode(s) in the common electrode layer (216) may be held on a reference potential, e.g., a signal ground, whereas the receiver electrode(s) in the receiver electrode layer (214) may be floating relative to the reference potential, based on the charge balance across the piezoelectric film (215). In order to enable a detection of a location of the force being applied to the piezoelectric film (215), the receiver electrode layer (214) and potentially the common electrode layer (216) may include patterned electrodes. The use of patterned electrodes to detect the location of the force being applied to the piezoelectric film (215), is discussed below in reference to FIGS. 6A and 6B.

In one or more embodiments, the cover layer (218) provides a protective surface of the sensing display module. The cover layer (218) may be a thin glass or plastic layer with mechanical characteristics that allow transmission of a force applied by an input object (e.g., finger (298)) to the piezoelectric film (215).

In one or more embodiments, the receiver electrode layer (214), the piezoelectric layer (215), the common electrode layer (216), and the cover layer (218) are substantially transparent, thereby enabling a user to see visual content displayed by the display (212).

Now referring to the touch circuit (250), in one or more embodiments, the touch circuit (250) receives a resulting signal (280) which, relative to a reference potential (270), reflects the charge balance across the piezoelectric film. In one or more embodiments, the resulting signal is processed by the touch circuit (250) to generate a touch/force signal (290) which may be indicative of the touch and/or force by the input object (298). The touch circuit (250) may perform various operations such as a charge integration, a low pass filtering, an analog-to-digital conversion, etc.

While FIG. 2 shows a single touch circuit (250), in one or more embodiments, multiple touch circuits may be used in conjunction with multiple receiver electrodes in the receiver electrode layer (214), as discussed in reference to FIGS. 6A and 6B. Alternatively, multiplexing may be used to read multiple receiver electrodes by a single touch circuit.

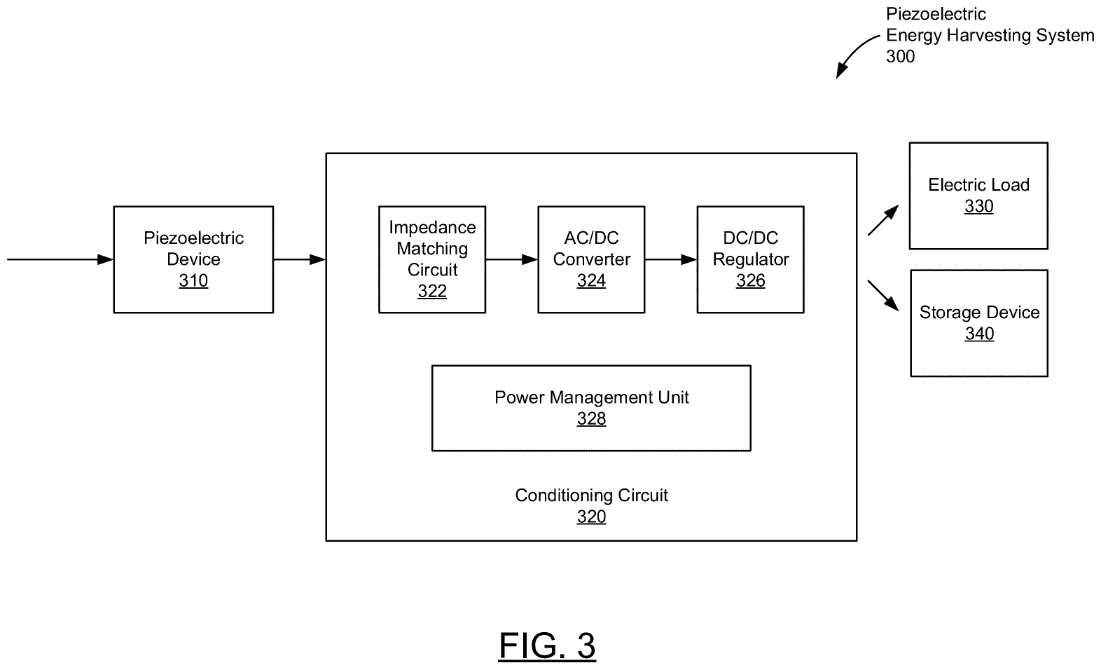

FIG. 3 shows an energy harvesting system in accordance with one or more embodiments. The piezoelectric energy harvesting system (300) transduces mechanical energy into electric energy. In one embodiment, a piezoelectric device (310) including one or more piezoelectric films is used as a transducer. As further discussed in reference to FIG. 5C, multiple piezoelectric films may be stacked to increase the amount of electric energy that is produced. A conditioning circuit (320) may convert the variable output produced by the piezoelectric device (310) into a DC voltage for the electric load (330). The conditioning circuit (320) may include an AC to DC converter (324) and a DC/DC voltage regulator (326), controlled by a power management unit (328) to manage the generated power as a function of the power load requirements and available power from the piezoelectric device (310). The conditioning circuit (320) may further include an impedance matching circuit (322) that ensures the maximum transfer of harvested electric energy. An energy storage device (340) may be used to store energy gathered by the harvesting unit in order to feed the electric load (330) under any operating condition. The energy storage device (340) may be, for example, a battery or super-capacitor.

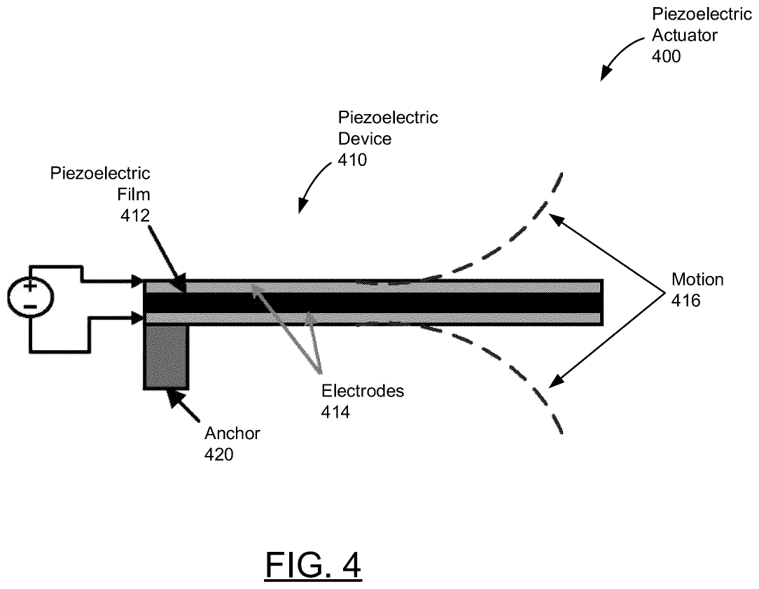

FIG. 4 shows an actuator in accordance with one or more embodiments. The piezoelectric actuator (400) produces a mechanical output, e.g., motion (416) in presence of an electric input, e.g., a voltage. The piezoelectric actuator (400) includes a piezoelectric device (410). The piezoelectric device (410) includes a piezoelectric film (412) and electrodes (414), e.g., as described below in reference to FIG. 5A. The piezoelectric device is mechanically anchored by an anchor (420). When a voltage is applied to the piezoelectric film (412), the piezoelectric material expands according to the polarization of the applied voltage, thereby causing an axial bending across the length of the piezoelectric film. As further discussed in reference to FIG. 5C, multiple piezoelectric films may be stacked to increase the motion amplitude and/or to enable more complex motion patterns, such as motion in multiple dimensions, e.g., three or more dimensions, including translational and/or rotational motions.

Turning to FIGS. 5A, 5B, and 5C, two configurations of piezoelectric sensors, in accordance with one or more embodiments, are shown.

Referring to FIG. 5A, the piezoelectric device (500) includes a piezoelectric film (510), a first electrode layer (520), and a second electrode layer (530). The first electrode layer may include one or more receiver electrodes (214) or one or more common electrodes (216). Similarly, the second electrode layer may include one or more receiver electrodes (214) or one or more common electrodes (216). The first electrode layer (520) and the second electrode layer (530), in one or more embodiments, are directly disposed on the piezoelectric film (510). In one or more embodiments, the first electrode layer and/or the second electrode layer include electrodes formed from a carbon nanotube (CNT) material. The CNT-based electrodes may be directly deposited onto the piezoelectric film (510).

Referring to FIG. 5B, the piezoelectric device (550) includes the elements of the piezoelectric device (500) of FIG. 5A and, in addition, a polyethylene terephthalate (PET) layer (570) and an adhesive (580). The PET layer (570) may be used as a substrate for depositing the second electrode layer (560). Accordingly, in the embodiment of FIG. 5B, only the first electrode layer (520) but not the second electrode layer (560) is directly deposited onto the piezoelectric film. The adhesive (580) may permanently bond the PET layer (570) with the second electrode layer (560) to the piezoelectric film (510). The piezoelectric device (550) may otherwise be similar to the piezoelectric device (500). In one or more embodiments, the first electrode layer and/or the second electrode layer include electrodes formed from a carbon nanotube (CNT) material. The CNT-based electrodes in the first electrode layer (520) may be directly deposited onto the piezoelectric film (510), whereas the CNT-based electrodes in the second electrode layer (560) may be directly deposited onto the PET layer (570).

Referring to FIG. 5C, the piezoelectric device (570) includes multiple piezoelectric devices (500) as shown in FIG. 5A. Any number of piezoelectric devices (500) may be stacked. An adhesive (590) may mechanically link the individual piezoelectric devices (500). To obtain a higher output voltage in response to a mechanical input, the individual piezoelectric devices (500) may be electrically connected in series. Alternatively, in a configuration that involves electrically driving the piezoelectric device (570), the stacking of multiple piezoelectric devices (500) may increase the motion amplitude that is produced and/or may enable more complex motion patterns, such as motion in multiple dimensions, e.g., three or more dimensions, including translational and/or rotational motions.

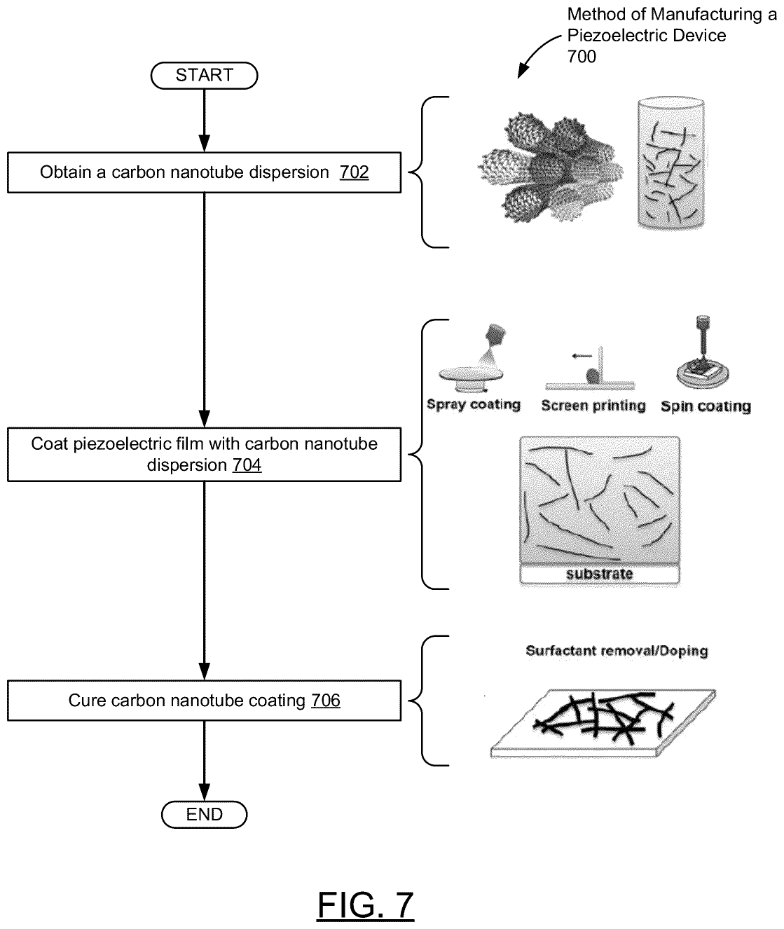

A detailed discussion of the manufacturing of the piezoelectric device of FIGS. 5A, 5B, and 5C, including the deposition of the CNT material onto the piezoelectric film and the resulting characteristics is provided below in reference to FIG. 7. Further, examples of the arrangement of the electrodes in the first and second layers (520, 530, 560) are provided in reference to FIGS. 6A and 6B.

Turning to FIG. 6A, an electrode pattern (600) is shown. The electrode pattern includes rows of receiver electrodes (602) and columns of common electrodes (604). The receiver electrodes (602) may be located in the first or second electrode layer of the piezoelectric device of FIGS. 5A, 5B, and 5C. Likewise, the common electrodes (604) may be located in the first or second electrode layer of the piezoelectric device of FIGS. 5A, 5B, and 5C. In the sensor pattern (600), the receiver electrodes (602) and the common electrodes (604) have rectangular shapes. The electrodes may have different shapes, without departing from the disclosure. For example, interconnected diamond-shaped electrode pads may be arranged in rows or columns. While not shown, the piezoelectric film (215) may located between the receiver electrodes (602) disposed on one surface of the piezoelectric film and the common electrodes (604) disposed on the other surface of the piezoelectric film, as previously discussed.

When operating a piezoelectric device as a sensing device, in one embodiment, the common electrodes (604) may be set to a reference potential, e.g., a signal ground, whereas the receiver electrodes (602) are floating. A resulting signal may be obtained for each of a pair of a receiver electrode (602) and a common electrode (604), e.g., using the touch circuit (250).

At the intersection of a receiver electrode (602) and a common electrode (604), a localized voltage measurement (corresponding to the touch/force signal (290)) may be performed to determine a local effect of a force acting on the piezoelectric film (215). The region of this localized voltage measurement may be termed a “sensing element” (606). While only a single sensing element (606) is identified in FIG. 6A, a sensing element (606) may exist at each intersection of a receiver electrode (602) and a common electrode (604). By performing a sensing operation for each of the sensing elements (606), the local effect of a force acting on the piezoelectric film (215) may, thus, be assessed across the entire (or part of) the piezoelectric film (215). The sensing operations may be performed in a scanning operation, e.g., row-by-row or column-by-column until an entire frame of sensing operations is completed. Each of the sensing operations may be performed by a touch circuit (250) as previously described. The result may be a set of touch/force signals, each indicative of a touch or force at a corresponding sensing element. The location at which the input object is actually applying the force to the piezoelectric element may subsequently be estimated. For example, the location may be determined to be at the sensing element with the touch/force signal having the highest voltage or highest voltage change over time. For increased accuracy, a spatial interpolation may be performed between multiple sensing elements, based on the corresponding force signals.

Turning to FIG. 6B, an electrode pattern (650) is shown. The electrode pattern includes a pattern of receiver electrodes (652) and a single common electrode (654) spanning the region of the receiver electrodes (652). The receiver electrodes (652) may be located in the first or second electrode layer of the piezoelectric device of FIGS. 5A, 5B, and 5C. Likewise, the common electrode (654) may be located in the first or second electrode layer of the piezoelectric device of FIGS. 5A, 5B, and 5C. In the sensor pattern (650), each of the receiver electrodes (652) is a pad which may have any shape.

In one embodiment, the common electrodes (654) may be set to a reference potential, e.g., signal ground, whereas the receiver electrodes (652) are floating. A resulting signal may be obtained for each receiver electrode (652), e.g., using the touch circuit (250).

A sensing element (656) is formed at each of the receiver electrodes (652). While the design of the electrode pattern (650) is different from the design of the electrode pattern (600), touch/force signals (one for each receiver electrode (652)) are obtained in a similar manner.

While FIGS. 6A and 6B show two types of electrode patterns, other types of electrode patterns may be used without departing from the disclosure. Also, non-patterned electrodes (e.g., solid-surface electrodes) may be used. Further, electrode patterns may be scaled in size and/or resolution, without departing from the disclosure.

Also, while FIGS. 1, 2, 3, 4, 5A, 5B, 5C, 6A, and 6B show configurations of components, other configurations may be used without departing from the scope of the disclosure. For example, various components may be combined to create a single component. As another example, the functionality performed by a single component may be performed by two or more components. Further, while piezoelectric devices have been described in conjunction with touch and/or force sensing, embodiments of the disclosure more generally relate to any type of piezoelectric devices, including piezoelectric sensors, energy harvesting devices, and actuators.

FIG. 7 shows a method (700) of manufacturing a piezoelectric device in accordance with one or more embodiments. More specifically, FIG. 7 illustrates the deposition of a carbon nanotube (CNT) material onto a substrate using a wet coating process. The substrate may be a piezoelectric film (e.g., a PVDF film) or another substrate such as a PET layer. While the various steps in FIG. 7 are presented and described sequentially, one of ordinary skill in the art will appreciate that some or all of the steps may be executed in different orders, may be combined or omitted, and some or all of the steps may be executed in parallel.

In Step 702, a carbon nanotube (CNT) dispersion or solution is prepared. The dispersion may be based on any liquid of any viscosity, e.g., water, ethanol, oil, a polymer, an epoxy resin, etc. A mechanical or chemical approach may be used to generate the dispersion. Mechanical approaches include, for example, ultrasonication and high-shear mixing. Chemical approaches include covalent methods involving functionalization, and non-covalent methods involving chemical moieties. Surfactants may be used to facilitate dispersion. In one embodiment, a nanotube solvent, capable of dissolution of the CNT molecules is used to create a CNT solution. As an example, the carbon nanotube solvent may be an acid, such as chlorosulfonic acid (HSO₃Cl), fluorosulfonic acid, fluorosulfuric acid, hydrochloric acid, methanesulfonic acid, nitric acid, hydrofluoric acid, fluoroantimonic acid, magic acid, or any other type of carborane-based acid. As another example, the nanotube solvent may be a supercritical fluid, which is a substance at a temperature and pressure above its critical point. The nanotube solvent as the supercritical fluid provides screening of the electrostatic interactions between solute molecules, in this case the CNT molecules, to negate surface tension effects and particle-particle interactions and enable solution. Past the critical point of the nanotube solvent, its temperature and pressure may be regulated to maintain maximum solubility of the CNT molecules such that the nanotube solvent in the supercritical state can be considered athermal for all effective purposes. As an example, the nanotube solvent as the super critical fluid can include supercritical carbon dioxide.

In one or more embodiments, additional components are added to the dispersion or solution. For example, silver nanowires may be mixed into the dispersion or solution. Any amount of silver nanowires may be added. For example, silver nanowires may be added to reach a concentration anywhere between 0.01 mg / ml and 0.1 mg / ml. In one or more embodiments, a doping of the CNTs may be performed. The doping may be performed on the CNTs prior to preparing the CNT solution or dispersion. Any type of doping may be performed. For example, an iodine vapor doping, an HNO₃ vapor doping an SOCl₂ vapor doping, and/or an MoO₃ vapor doping may be performed. The doping and/or addition of components to the dispersion or solution may be performed for any reason. In one or more embodiments, the doping and/or addition of components to the dispersion or solution is performed to lower the resistance of the CNTs.

In Step 704, the substrate, e.g., the piezoelectric film, is coated with the CNT nanotube dispersion or solution to form an electrode layer on the substrate. Any type of coating method such as spray coating, screen printing, spin coating, blade coating, dip coating, vacuum filtration coating, etc., may be used. The selection of the coating method may depend on the desired type of electrode layer. For example, screen printing may be more suitable for generating a patterned electrode, whereas spin coating may be more suitable for generating a homogenous, non-patterned electrode. The selection of the coating method may further depend on the viscosity of the CNT dispersion or solution. Step 504 may be performed for one side of the piezoelectric film, or for both sides.

In Step 506, the carbon nanotube coating (706) is cured. Any type of curing method that is not detrimental to the piezoelectric film may be used. For example, if a curing under elevated temperature is performed, the temperature is kept under the Curie temperature of the piezoelectric material of the piezoelectric film. For example, a curing at room temperature or at a slightly elevated temperature, e.g., at 60-70° C. may be performed.

Additional steps may be performed without departing from the disclosure.

For example, upon completion of the curing of the CNT coating, an electrical interface to the electrode(s) in the electrode layer(s) may be established. The electrical interface may include contact pads on the surface of the electrode layer(s). Further, assembly operations may be performed to integrate the piezoelectric device with other components. The assembly operations may include steps such as gluing or otherwise attaching additional layers to the piezoelectric device.

The manufacturing of a piezoelectric device in accordance with embodiments of the disclosure may have various benefits. In particular, the piezoelectric material of the piezoelectric film may maintain its piezoelectricity, because a wet coating process is used. Accordingly, unlike in other processes such as physical vapor deposition (PVD) used for the deposition of tin doped iridium (ITO), no significant heat is applied. In addition, the wet coating process is cost effective in comparison to a PVD process. Yet, a high level of transparency of the electrodes is achievable using the CNT-based electrodes. An additional advantage may be that, unlike ITO films which are known to be rigid and brittle, CNT-based electrodes may have a high level of flexibility and durability. Further, CNT-based electrodes are known to be environmentally stable, thereby reducing the cost to meet environmental standards.

The following example of a piezoelectric device in accordance with embodiments of the disclosure provides performance characteristics. Embodiments of the disclosure are not limited to this example.

In one embodiment, the piezoelectric film has certain characteristics. For example, the sensitivity (expressed as an electric charge in response to a force being applied, i.e., a piezoelectric coefficient, d₃₁) may be greater than 10 pC/N or greater than 20 pC/N. Also, the piezoelectric film may have any thickness, e.g., in a range of 10-200 μm. The optical transmittance of the piezoelectric film may be at least 90% or at least 95%. The optical haze optical transmittance of the piezoelectric film may be less than 10% or less than <5%.

In one embodiment, a CNT-based electrode has certain characteristics. For example, in order to obtain an increased signal-to-noise ratio (SNR), the sheet resistance across the CNT-based electrode layer may be kept low. The sheet resistance may be less than 300 ohm/sq., less than 100 ohm/sq. or less than 50 ohm/sq. The optical transmittance of the CNT-based electrode layer may be at least 90% or at least 95%. The optical haze optical transmittance of the CNT-based electrode layer may be less than 10% or less than <5%.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.

What is claimed:

1. A piezoelectric device, comprising:
a piezoelectric film; and
a first carbon-nanotube(CNT)-based electrode layer directly disposed on at least one side of the piezoelectric film, wherein the CNT-based first electrode layer has a sheet resistance of less than 300 ohm/sq.

2. The piezoelectric device of claim 1, wherein the piezoelectric film is one selected from a group consisting of a polyvinylidene fluoride (PVDF) piezoelectric film, a PVDF copolymer film, a polylactic acid piezo-biopolymer film, a polyurea film, a polyurethane film, a polyamide film, a polyacrylonitrile film, a polyimide, and a polypropylene film.

3. The piezoelectric device of claim 1, wherein the piezoelectric film has an optical transmittance of at least 90%.

4. The piezoelectric device of claim 1, wherein the piezoelectric film has an optical haze of less than 5%.

5. The piezoelectric device of claim 1, wherein the piezoelectric film has a thickness in a range between 10 μm and 200 μm.

6. The piezoelectric device of claim 1, wherein the piezoelectric film has a piezoelectric coefficient, d₃₁, of at least 10 pC/N.

7. The piezoelectric device of claim 1, wherein the first CNT-based electrode layer comprises silver nanowires.

8. The piezoelectric device of claim 1, wherein the first CNT-based electrode layer is doped with at least one selected from a group consisting of iodine, HNO₃, SOCl₂, and MoO_{3.}

9. The piezoelectric device of claim 1, wherein the first CNT-based electrode layer has an optical transmittance of at least 90%.

10. The piezoelectric device of claim 1, wherein the first CNT-based electrode layer has an optical haze of less than 5%.

11. The piezoelectric device of claim 1, wherein the piezoelectric device is one selected from a group consisting of sensing device, an energy harvesting device, and an actuator.

12. The piezoelectric device of claim 1, further comprising a second CNT-based electrode layer directly disposed on the piezoelectric film.

13. A method of manufacturing a piezoelectric device, the method comprising:
obtaining a carbon nanotube (CNT) dispersion;
coating a piezoelectric film with the CNT dispersion to obtain a CNT-based electrode layer directly disposed on the piezoelectric film; and
curing the CNT-based electrode layer,
wherein the CNT-based electrode layer has a sheet resistance of less than 300 ohm/sq.

14. The method of claim 13, wherein the coating comprises one selected from a group consisting of a spray coating, a screen printing, a spin coating, a blade coating, a dip coating, and a vacuum filtration coating.

15. The method of claim 13, wherein the curing comprises exposing the CNT-based electrode layer to a temperature of no more than the Curie temperature of the piezoelectric film.

16. The method of claim 13, wherein obtaining the CNT dispersion comprises adding at least one selected from a group consisting of silver nanowires, metal mesh, conductive polymer, and graphene to the CNT dispersion.

17. The method of claim 13, wherein obtaining the CNT dispersion comprises doping the CNT dispersion with at least one selected from a group consisting of iodine, HNO₃, SOCl₂, and MoO_{3.}

18. A piezoelectric input device, comprising:
a piezoelectric device, comprising:
a piezoelectric film; and
a first carbon-nanotube(CNT)-based electrode layer directly disposed on at least one side of the piezoelectric film, wherein the CNT-based first electrode layer has a sheet resistance of less than 300 ohm/sq and forms a plurality of receiver electrodes; and
a processing system for determining the position of the input object based on resulting signals obtained from the plurality of receiver electrodes.

19. The piezoelectric input device of claim 18, wherein the piezoelectric film is one selected from a group consisting of a polyvinylidene fluoride (PVDF) piezoelectric film, a PVDF copolymer film, a polylactic acid piezo-biopolymer film, a polyurea film, a polyurethane film, a polyamide film, a polyacrylonitrile film, a polyimide, and a polypropylene film.

20. The piezoelectric input device of claim 18, wherein the first CNT-based electrode layer comprises silver nanowires.
